(19) United States
(12) Patent Application Publication
(10) Pub. No.: US 2025/0331335 A1
(43) Pub. Date: Oct. 23, 2025

(54) MICRO LIGHT-EMITTING DIODE AND DISPLAY APPARATUS HAVING SAME

(71) Applicant: XIAMEN SAN'AN OPTOELECTRONICS CO., LTD., Xiamen (CN)

(72) Inventors: Boqi ZHAN, Xiamen (CN); Xueping YE, Xiamen (CN); Kechuang LIN, Xiamen (CN); TE-LING HSIA, Xiamen (CN); Chia-En LEE, Xiamen (CN)

(21) Appl. No.: 19/253,938

(22) Filed: Jun. 29, 2025

Related U.S. Application Data
(63) Continuation of application No. PCT/CN2023/136138, filed on Dec. 4, 2023.

(30) Foreign Application Priority Data
Dec. 30, 2022 (CN) 202211732401.7

(51) Int. Cl. H10H 20/821; H01L 25/075; H10H 20/857

(52) U.S. Cl. CPC H10H 20/821; H01L 25/0753; H10H 20/857

(57) ABSTRACT

A micro light-emitting diode (micro-LED) and a display apparatus are provided. The micro-LED includes a semiconductor layer sequence, which has a back side and a front side. The semiconductor layer sequence includes: a first-type semiconductor layer, a second-type semiconductor layer, and an active layer therebetween. The back side is provided with a groove, the groove penetrates through the second-type semiconductor layer and the active layer, and the first-type semiconductor layer is exposed through the groove. The back side includes: a first mesa, a second mesa, and a groove sidewall. A first metal electrode and a second metal electrode are disposed on the back side. The first metal electrode and the second metal electrode are configured for bonding with an external power supply. The first metal electrode is entirely disposed within the groove, to prevent the first metal electrode from bridging onto the second mesa.

### CROSS-REFERENCE TO RELATED APPLICATIONS

This application is a continuation of International Application No. PCT/CN2023/136138, filed Dec. 4, 2023, which claims the priority of Chinese Patent Application No. CN202211732401.7, filed Dec. 30, 2022, both of which are herein incorporated by reference in their entirety.

### TECHNICAL FIELD

The present disclosure relates to the field of semiconductor manufacturing technologies, and particularly to a micro light-emitting diode (micro-LED) and a display apparatus.

### BACKGROUND

A micro-LED (mLED) is currently a hot topic of research as a next-generation display light source. The mLED features a lower power consumption, a higher brightness, ultra-high resolution and color saturation, a faster response time, a lower energy consumption, and a longer lifespan. In addition, a power consumption of the mLED is only about 10% of a power consumption of a liquid crystal display (LCD) and 50% of a power consumption of an organic light-emitting diode (OLED). Compared with the OLED, which can also achieve self-emitting, the mLED offers much higher brightness and can achieve a higher pixel density resolution. These significant advantages of the mLED make it be a promising candidate to replace the OLED and the LCD, and become a light source for a next-generation display. However, the mLED is not yet mass-producible because there are still many technical challenges to overcome. One of key challenges is how to improve the production yield of micron-scale chiplets.

### SUMMARY

To improve a process yield, such as a chip yield or a transfer yield, of micro-LEDs, in one aspect, the present disclosure provides a micro-LED, which can effectively enhance the process yield of micro-LEDs. The micro-LED includes a semiconductor layer sequence. The semiconductor layer sequence has a back side and a front side opposite to the back side. In a direction from the front side to the back side, the semiconductor layer sequence sequentially includes: a first-type semiconductor layer, a second-type semiconductor layer, and an active layer between the first-type semiconductor layer and the second-type semiconductor layer. The back side of the semiconductor layer sequence is provided with a groove, the groove penetrates through the second-type semiconductor layer and the active layer, and the first-type semiconductor layer is exposed through the groove. The back side of the semiconductor layer sequence includes: a first mesa within the groove, a second mesa on the second-type semiconductor layer, and a groove sidewall located between the first mesa and the second mesa. A first metal electrode and a second metal electrode are disposed on the back side of the semiconductor layer sequence. The first metal electrode is electrically connected to the first-type semiconductor layer, and the second metal electrode is electrically connected to the second-type semiconductor layer. The first metal electrode and the second metal electrode are configured for bonding with an external power supply. The first metal electrode is entirely disposed within the groove, to prevent it from bridging onto the second mesa.

In an embodiment, the micro-LED is rectangular, a length of a shorter side of the micro-LED is not more than 20 μm, a length of a longer side of the micro-LED is not more than 30 μm, and a length of each side of the first mesa is not more than 20 μm. The smaller the chip size, the smaller the area of the first metal electrode. Equal-height surfaces of the first metal electrode and the second metal electrode are used for bonding with the external power supply. If the first metal electrode spans over to the second mesa, it will cause a significant reduction in an area of the equal-height surfaces of the first metal electrode and the second metal electrode, resulting in insufficient bonding strength.

In an embodiment, the groove is an unenclosed step, three side surfaces of four side surfaces of the groove are exposed, and the remaining side surface of the four side surfaces of the groove is the groove sidewall. Through this technical solution, it is beneficial to reduce a process margin and increase an effective luminous area.

In an embodiment, the micro-LED includes a first insulating layer and a second insulating layer. The first insulating layer defines a first opening disposed on the first mesa. The first metal electrode is partially disposed on the first mesa. The first metal electrode extends from the first mesa within the first opening onto the first insulating layer. The second insulating layer is disposed on the second mesa and defines a second opening disposed on the second mesa. The second metal electrode is partially disposed on the second mesa. The second metal electrode extends from the second mesa within the second opening onto the second insulating layer.

In an embodiment, a backside surface of the first metal electrode defines a first electrode hole, which corresponds in position to the first opening; and the backside surface of the second metal electrode defines the second electrode hole, which corresponds in position to the second opening. An opening area of the first electrode hole is smaller than an opening area of the second electrode hole. The reduction in the opening area of the first electrode hole is helpful to reduce an area of the first mesa and increase an effective luminous area.

In an embodiment, as a size of a chiplet decreases; while being constrained by process limitations, an opening area of the insulating layer has a minimum process value. An opening area of the first electrode hole accounts for 10% to 90% of an area of the backside surface of the first metal electrode, and an opening area of the second electrode hole accounts for 10% to 90% of an area of the backside surface of the second metal electrode.

In an embodiment, by adjusting materials of the first insulating layer and the second insulating layer, the opening area of each of the first insulating layer and the second insulating layer is further reduced. An opening area of the first electrode hole accounts for 10% to 40% of an area of the backside surface of the first metal electrode, and an opening area of the second electrode hole accounts for 10% to 40% of an area of the backside surface of the second metal electrode.

In an embodiment, due to the reduction in a chip size, the areas of the first metal electrode and the second metal electrode are limited. Therefore, a projected area of the backside surface of the first metal electrode and a projected area of the backside surface of the second metal electrode are no greater than 100 μm².

In an embodiment, a spacing between the first metal electrode and the second metal electrode is in a range from 4 μm to 10 μm.

In an embodiment, after performing a substrate lift-off process and a partial removal process of the first-type semiconductor layer, at least part of the first-type semiconductor layer of the micro-LED is removed.

In another aspect, the present disclosure further provides a display apparatus. The display apparatus includes a circuit board and the micro-LED described above. The micro-LED is electrically connected to the circuit board via a bonding layer.

Beneficial effects of the present disclosure at least include: by optimizing a chip structure and/or manufacturing process, the production yield and process yield of micron-level chips are improved, production costs are reduced, and the industrialization of micron-level chips is promoted.

### BRIEF DESCRIPTION OF DRAWINGS

To provide a clearer explanation of the technical solutions in the embodiments of the present disclosure or the prior art, the accompanying drawings used in the description of the embodiments or the prior art will be briefly introduced below. Apparently, some of the drawings in the following description pertain to certain embodiments of the present disclosure. For those of ordinary skill in the art, other drawings may also be obtained from these accompanying drawings without creative effort.

FIG. 1 and FIG. 2 respectively illustrate a top view and a cross-sectional view of a micro-LED in the prior art.

FIG. 3 and FIG. 4 respectively illustrate a top view and a cross-sectional view of a micro-LED according to an embodiment 1 of the present disclosure.

FIG. 5 and FIG. 6 respectively illustrate a top view and a cross-sectional view of a micro-LED according to an embodiment 2 of the present disclosure.

FIG. 7 and FIG. 8 respectively illustrate a top view and a cross-sectional view of a micro-LED according to an embodiment 3 of the present disclosure.

FIG. 9 and FIG. 10 illustrate schematic diagrams illustrating a mass transfer process of the micro-LED according to the embodiment 3 of the present disclosure.

FIG. 11 illustrates a cross-sectional view of a micro-LED according to an embodiment 4 of the present disclosure.

FIG. 12 illustrates a cross-sectional view of a micro-LED according to an embodiment 5 of the present disclosure.

### DETAILED DESCRIPTION OF EMBODIMENTS

To make the objectives, technical solutions, and advantages of the embodiments of the present disclosure clearer, the technical solutions in the embodiments of the present disclosure will be described clearly and completely in conjunction with the accompanying drawings in the embodiments of the present disclosure. It is apparent that the described embodiments are only a part of embodiments of the present disclosure, not all of them. The technical features involved in the different implementations of the present disclosure described below can be combined as long as they do not conflict with each other. Based on the embodiments of the present disclosure, all other embodiments obtained by those of ordinary skill in the art without creative effort shall fall within the protection scope of the present disclosure.

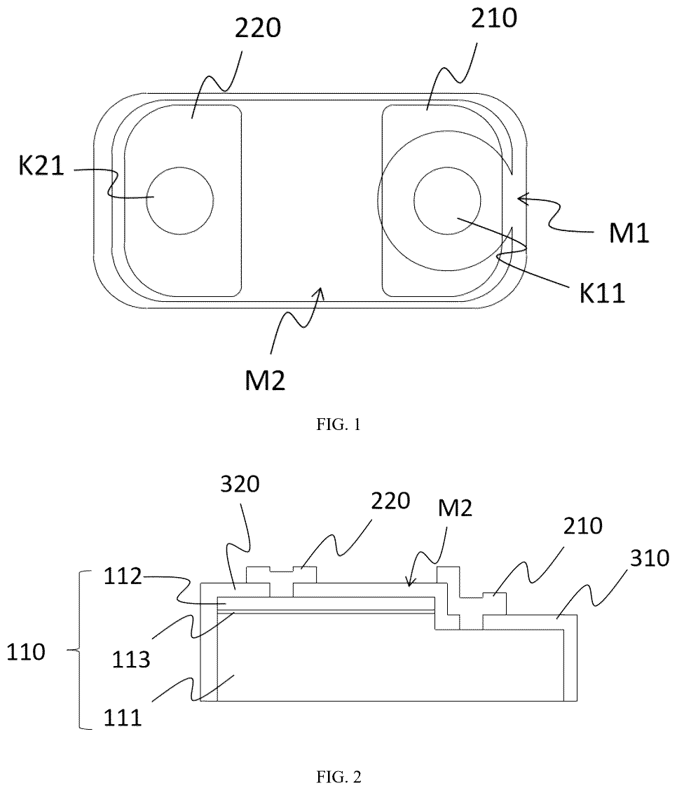

Referring to FIG. 1 and FIG. 2, as a comparative example, in the prior art, to improve product pixel density, reduce production costs, and meet the continuously proposed demand for shrinking chip size, a groove design is applied to a semiconductor layer sequence 110 of a chip (i.e., a micro-LED) based on the requirements for equal-height design of a first metal electrode 210 and a second metal electrode 220 and reducing a number of photomasks. However, since the first metal electrode 210 bridges onto a second mesa M2, an area of regions where the first metal electrode 210 and the second metal electrode 220 are of an equal height is limited. As a result, a bonding yield of the micro-LED cannot meet a required level when it is bonded to an external circuit.

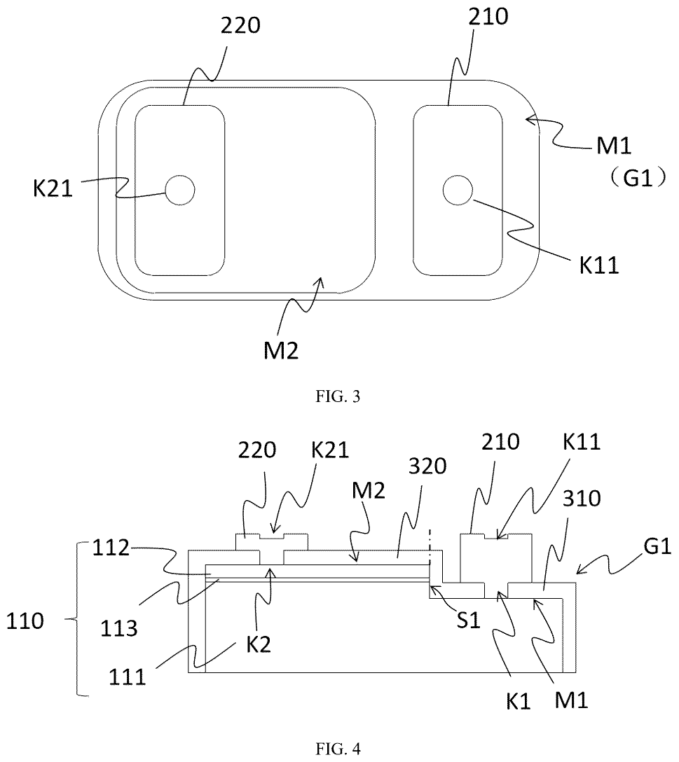

Referring to FIG. 3 and FIG. 4, in an embodiment 1 of the present disclosure, a micro-LED is provided. In this embodiment, the micro-LED is rectangular, a length of a shorter side of the micro-LED is in a range from 10 μm to 20 μm, and a length of a longer side of the micro-LED is in a range from 15 μm to 30 μm. For example, the micro-LED may have a dimension of 10 μm×25 μm. The micro-LED includes a semiconductor layer sequence 110, which has a back side and a front side. In a direction from the front side to the back side, the semiconductor layer sequence 110 sequentially includes a first-type semiconductor layer 111, a second-type semiconductor layer 112, and an active layer 113 located between the first-type semiconductor layer 111 and the second-type semiconductor layer 112. The first-type semiconductor layer 111 of the micro-LED is at least partially removed from the front side, for example, through substrate stripping and epitaxial thinning processes. The back side of the semiconductor layer sequence 110 is provided with a groove G1, which serves as a mesa groove. The groove G1 penetrates through the second-type semiconductor layer 112 and the active layer 113, and the first-type semiconductor layer 111 is partially exposed through the groove G1. The back side of the semiconductor layer sequence 110 includes a first mesa M1 within the groove G1, a second mesa M2 on the second-type semiconductor layer 112, and a groove sidewall S1 located between the first mesa M1 and the second mesa M2. The back side of the semiconductor layer sequence 110 is provided with a first metal electrode 210 electrically connected to the first-type semiconductor layer 111 and a second metal electrode 220 electrically connected to the second-type semiconductor layer 112. The first metal electrode 210 and the second metal electrode 220 are used for bonding with an external power supply. The first metal electrode 210 is entirely disposed within the groove G1.

In this embodiment, a length of each side of the first mesa M1 is not more than 20 μm. The groove G1 is an unenclosed step, three side surfaces of four side surfaces of the groove are exposed, and the remaining side surface of the four side surfaces of the groove is the groove sidewall S1. That is, the first mesa M1 is formed by using a three-sided open design manner.

In this embodiment, the micro-LED further includes a first insulating layer 310 and a second insulating layer 320. The first insulating layer 310 defines a first opening K1, which is disposed on the first mesa M1. The first metal electrode 210 is partially disposed in the first opening K1 and is disposed on the first mesa M1. The first metal electrode 210 extends from the first mesa M1 within the first opening K1 onto the first insulating layer 310. The second insulating layer 320 is disposed on the second mesa M2 and defines a second opening K2, which is disposed on the second mesa M2. The second metal electrode 220 is partially disposed on the second mesa M2 and extends from the second mesa M2 within the second opening K2 onto the second insulating layer 320.

In this embodiment, a backside surface of the first metal electrode 210 defines a first electrode hole K11 corresponding in position to the first opening K1, and a backside surface of the second metal electrode 220 defines a second electrode hole K21 corresponding in position to the second opening K2. The first metal electrode 210 is entirely disposed on the first mesa M1 and the first insulating layer 310, the second metal electrode 220 is entirely disposed on the second mesa M2 and the second insulating layer 320, the backside surfaces of the first metal electrode 210 and the second metal electrode 220 are of an equal height except at positions of the backside surfaces corresponding to the first electrode hole K11 and the second electrode hole K21. In some implementations, a transparent current spreading layer may be provided between the second metal electrode 220 and the second-type semiconductor layer 112.

In this embodiment, the second mesa M2 is rectangular, and a length or a width of the second mesa M2 is in a range from 5 μm to 20 μm. Experiments show that a rectangular shape helps improve current density in small-sized products, thereby enhancing brightness.

In this embodiment, an opening area of the first electrode hole K11 accounts for 10% to 90% of an area of the backside surface of the first metal electrode 210, and an opening area of the second electrode hole K21 accounts for 10% to 90% of an area of the backside surface of the second metal electrode 220.

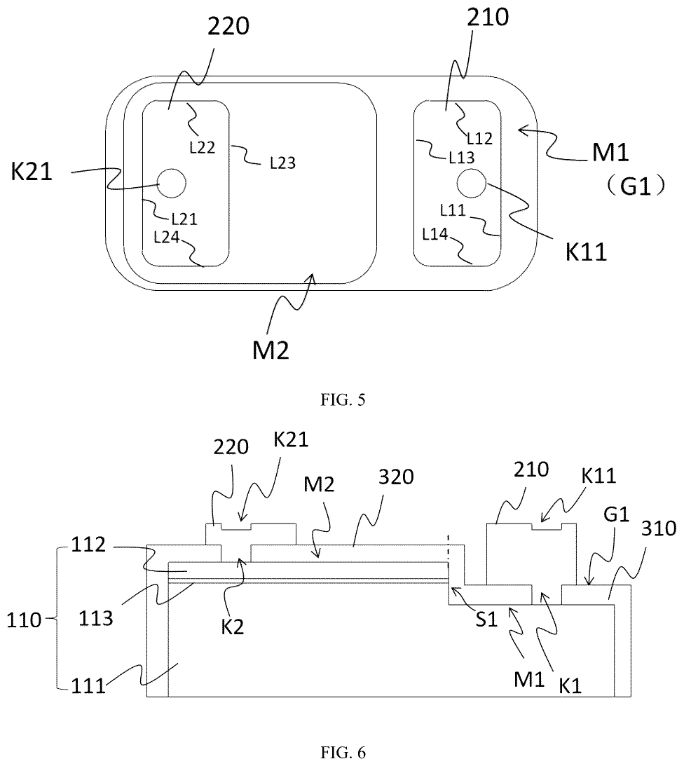

Referring to FIG. 5 and FIG. 6, in an embodiment 2 of the present disclosure, considering that the first electrode hole K11 and the second electrode hole K21 may cause poor distribution continuity of the equal-height regions on the backside surfaces of the first metal electrode 210 and the second metal electrode 220, this embodiment adopts an eccentric design for the first electrode hole K11 and the second electrode hole K21 to further optimize the bonding yield between the metal electrodes and the external circuit.

The first electrode hole K11 is a circular hole with a diameter of 2 μm to 4 μm, and its center is not located at a center of the backside surface of the first metal electrode 210. From a projection of the first metal electrode 210 in the direction from the back side to the front side of the semiconductor layer sequence 110, the backside surface of the first metal electrode 210 is rectangular and includes a first side L11, a second side L12, a third side L13, and a fourth side L14 sequentially connected in that order.

In some implementations, a side length of each of the first metal electrode 210 and the second metal electrode 220 ranges from 3 μm to 8 μm. From projections of the first metal electrode 210 and the second metal electrode 220 in the direction from the back side to the front side of the semiconductor layer sequence 110, the first metal electrode 210 and the second metal electrode 220 are rectangular.

The second electrode hole K21 is a circular hole with a diameter of 2 μm to 4 μm, and its center is not located at a center of the backside surface of the second metal electrode 220. From a projection of the second metal electrode 220 in the direction from the back side to the front side of the semiconductor layer sequence 110, the backside surface of the second metal electrode 220 is rectangular and includes a first side L21, a second side L22, a third side L23, and a fourth side L24 sequentially connected in that order.

In some implementations, the second electrode hole K21 is located near a corner of the second metal electrode 220, i.e., a spacing between the second electrode hole K21 and the center of the second metal electrode 220 ranges from 1.5 μm to 3 μm. A spacing from the second electrode hole K21 to the first side L21 is less than half of a spacing from the second electrode hole K21 to the third side L23, and a spacing from the second electrode hole K21 to the second side L22 is less than half of a spacing from the second electrode hole K21 to the fourth side L24.

In this embodiment, an opening area of the first electrode hole K11 accounts for 10% to 40% of an area of the backside surface of the first metal electrode 210, and/or an opening area of the second electrode hole K21 accounts for 10% to 40% of an area of the backside surface of the second metal electrode 220. A projected area of the backside surface of the first metal electrode 210 and a projected area of the backside surface of the second metal electrode 220 are each no greater than 100 μm².

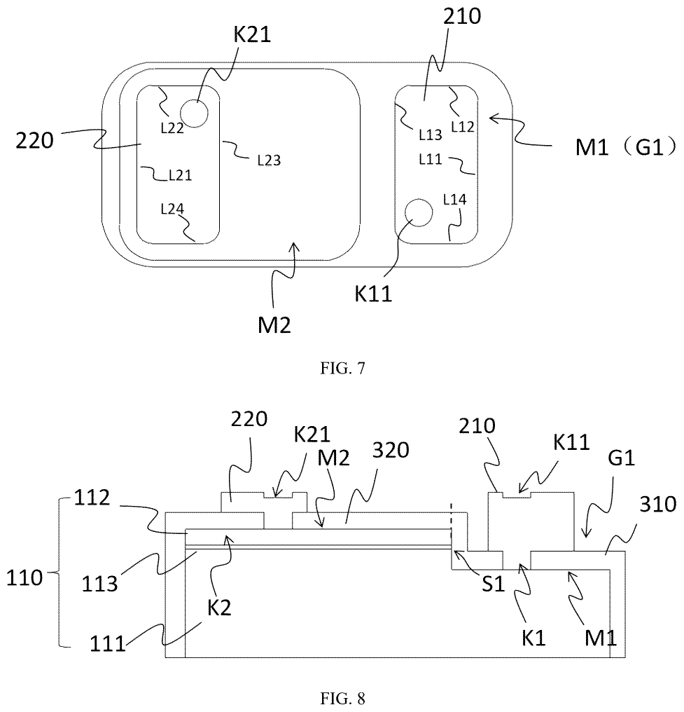

Referring to FIG. 7 and FIG. 8, in an embodiment 3 of the present disclosure, based on the previous embodiments 1 and 2, improvements are made to a micro-LED, in the embodiment 3, a spacing between the first metal electrode 210 and the second metal electrode 220 is in a range from 4 μm to 10 μm. Here, the spacing refers to a minimum distance between the two electrodes. Due to chip size constraints, when the spacing is too small, the equal-height surfaces of the first metal electrode 210 and the second metal electrode 220 are too close, making it difficult to form effective support.

The first electrode hole K11 is a circular hole with a diameter of 2 μm to 4 μm, and its center is not located at a center of the backside surface of the first metal electrode 210. From a projection of the first metal electrode 210 in the direction from the back side to the front side of the semiconductor layer sequence 110, the backside surface of the first metal electrode 210 is rectangular and includes a first side L11, a second side L12, a third side L13, and a fourth side L14 sequentially connected in that order. The first side L11 is close to and parallel to the shorter side of the micro-LED, and the second side L12 and the fourth side L14 are parallel to the longer side of the micro-LED.

In some implementations, a side length of each of the first metal electrode 210 and the second metal electrode 220 ranges from 3 μm to 8 μm. From projections of the first metal electrode 210 and the second metal electrode 220 in the direction from the back side to the front side of the semiconductor layer sequence 110, both the first metal electrode 210 and the second metal electrode 220 are rectangular.

The second electrode hole K21 is a circular hole with a diameter of 2 μm to 4 μm, and its center is not located at a center of the backside surface of the second metal electrode 220. From a projection of the second metal electrode 220 in the direction from the back side to the front side of the semiconductor layer sequence 110, the backside surface of the second metal electrode 220 is rectangular and includes a first side L21, a second side L22, a third side L23, and a fourth side L24 sequentially connected in that order. The first side L21 is close to and parallel to the shorter side of the micro-LED, while the second side L22 and the fourth side L24 are parallel to the longer side of the micro-LED. A spacing from the second electrode hole K21 to the third side L23 is less than a spacing from the second electrode hole K21 to the first side L21. In this embodiment, the spacing from the second electrode hole K21 to the third side L23 is less than half of the spacing from the second electrode hole K21 to the first side L21, where the corresponding spacing refers to a shortest distance from an edge of the second electrode hole K21 to the first side L21 or the third side L23.

In some embodiments, the second electrode hole K21 is disposed on a side of the second metal electrode 220 closer to the first metal electrode 210, ensuring that a bonding surface of the second metal electrode 220 is primarily located on a side of the second metal electrode 220 farther from the first metal electrode 210. In this embodiment, the second electrode hole K21 is positioned at any corner of the second metal electrode 220 near the first metal electrode 210. Correspondingly, the first electrode hole K11 may be disposed on a side of the first metal electrode 210 closer to the second metal electrode 220. The first electrode hole K11 and the second electrode hole K21 are diagonally arranged relative to a center of the micro-LED. A spacing between the second electrode hole K21 and a center of the second metal electrode 220 ranges from 1.5 μm to 3 μm. A spacing from the second electrode hole K21 to the third side L23 is less than half of a spacing from the second electrode hole K21 to the first side L21, and a spacing from the first electrode hole K11 to the third side L13 is less than half of a spacing from the first electrode hole K11 to the first side L11. A spacing between the second electrode hole K21 and the first metal electrode 210 is no less than 5 μm. In some implementations of this embodiment, the spacing between the second electrode hole K21 and the first metal electrode 210 ranges from 5 μm to 10 μm.

In this embodiment, an opening area of the first electrode hole K11 accounts for 10% to 40% of an area of the backside surface of the first metal electrode 210, and/or an opening area of the second electrode hole K21 accounts for 10% to 40% of an area of the backside surface of the second metal electrode 220. A projected area of the backside surface of the first metal electrode 210 and a projected area of the backside surface of the second metal electrode 220 are each no greater than 100 μm².

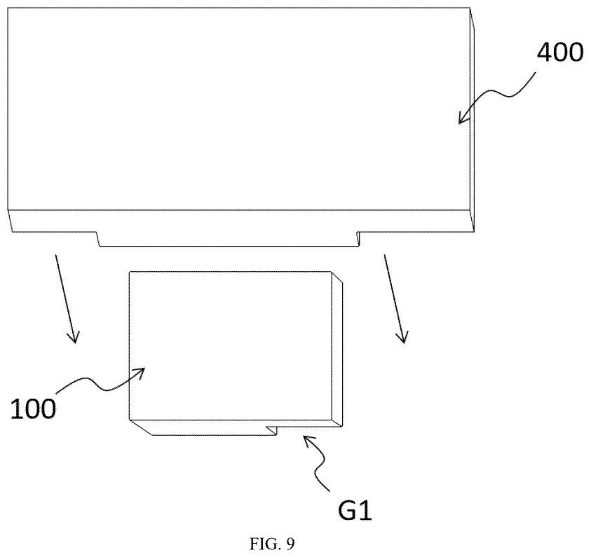

Referring to FIG. 9 and FIG. 10, in some implementations, micro-LEDs may undergo stamping transfer processes, such as in high-pixel display chip manufacturing, where a size of the micro-LED 100 is within 100 μm×150 μm, and a front side of the first-type semiconductor layer is at least partially removed or thinned, with a native substrate stripped. The manufacturing process involves stamping and imprinting, picking up, and placing by ultra-thin and/or small devices. The design in this embodiment enables micro-transfer printing, allowing the selection and application of these ultra-thin, fragile, and/or miniaturized devices without causing chip rotation. Since the first metal electrode 210, the second metal electrode 220, and the semiconductor layer sequence 110 are axially symmetric along a longer side of the semiconductor layer sequence 110, the corresponding micro-LED does not rotate or shift during mass transfer. The asymmetry of the electrode holes is negligible in the present disclosure.

A mass transfer method of microtransfer printing allows for deterministic assembly and integration of micro-scale and high-performance device arrays onto non-native substrates. In a simplest implementation, microtransfer printing is similar to using a rubber stamper to transfer fluid-based ink from a printing plate to paper. However, in the microtransfer printing, the “ink” consists of high-performance solid-state semiconductor devices, and the “paper” may be a substrate containing a circuit board, adhesive film, plastic, or other semiconductors. The microtransfer printing process utilizes a designed elastomer stamper 400 coupled with a high-precision control printing head to selectively pick up and print large arrays of micro-scale devices onto a non-native substrate.

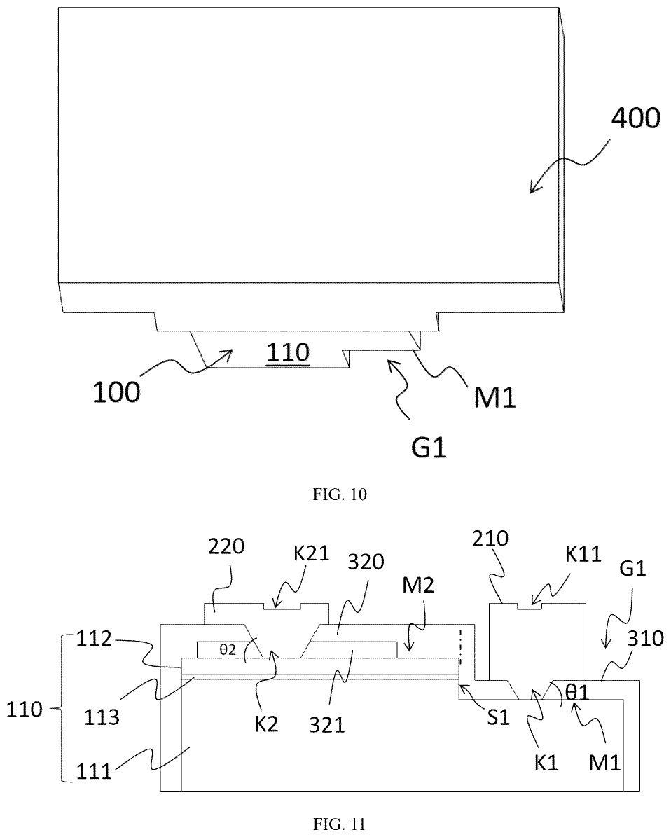

Referring to FIG. 11, in an embodiment 4 of the present disclosure, a micro-LED is provided. A back side of the semiconductor layer sequence 110 includes a first mesa M1 within a groove G1, a second mesa M2 on a second-type semiconductor layer 112, and a groove sidewall S1 located between the first mesa M1 and the second mesa M2. In some micro-LED processes, a frontside surface of the first-type semiconductor layer 111 is used to cooperate with the stamp 400 for massive transfer.

On the back side of the semiconductor layer sequence 110, a first metal electrode 210 electrically connected to the first-type semiconductor layer 111 and a second metal electrode 220 electrically connected to the second-type semiconductor layer 112 are disposed. In this embodiment, the first metal electrode 210 is disposed to connect with the first-type semiconductor layer 111, and the second metal electrode 220 is disposed to connect with the second-type semiconductor layer 112. As one implementation, a current spreading layer, such as a transparent conductive layer, may also be disposed between the second metal electrode 220 and the second-type semiconductor layer 112.

In this embodiment, the micro-LED further includes a first insulating layer 310 and a second insulating layer 320. The first insulating layer 310 includes silicon oxide and/or silicon nitride; and the second insulating layer 320 includes silicon oxide, silicon nitride, and titanium oxide. The first insulating layer 310 has fewer material types than the second insulating layer 320, and the second insulating layer 320 includes materials of the first insulating layer 310. The first insulating layer 310 defines a first opening K1 disposed on the first mesa M1, and an angle between a sidewall of the first opening K1 and the first mesa M1 is θ1. The first metal electrode 210 is at least partially disposed on the first mesa M1 and extends from the first mesa M1 within the first opening K1 onto the first insulating layer 310. The second insulating layer 320 is disposed on the second mesa M2 (a dashed line in FIG. 11 merely illustrates the arrangement of the second insulating layer 320). The second insulating layer 320 includes a part of the first insulating layer 310, and the first insulating layer 310 extends from the first mesa M1 along the groove sidewall S1 onto the second mesa M2. The second insulating layer 320 defines a second opening K2 disposed on the second mesa M2. The second metal electrode 220 is at least partially disposed on the second mesa M2 and extends from the second mesa M2 within the second opening K2 onto the second insulating layer 320. An aperture of the second opening K2 ranges from 1 μm to 5 μm. By appropriately enlarging the aperture of the second opening K2, the etching conditions can be improved, and an angle θ2 between a sidewall of the second opening K2 and the second mesa M2 can be reduced. The backside surface of the first metal electrode 210 defines a first electrode hole K11 corresponding in position to the first opening K1, and the backside surface of the second metal electrode 220 defines a second electrode hole K21 corresponding in position to the second opening K2. An opening area of the first electrode hole K11 is smaller than that of the second electrode hole K21.

In this embodiment, a thickness of the second insulating layer 320 is greater than that of the first insulating layer 310. The thickness of the first insulating layer 310 is ¼ to ⅔ of the thickness of the second insulating layer 320. Specifically, the thickness of the first insulating layer 310 ranges from 0.5 μm to 2 μm, and the thickness of the second insulating layer 320 ranges from 1 μm to 3 μm. Reducing the thickness of the first insulating layer 310 is helpful to improve the production yield of the first metal electrode 210, avoiding metal cracking around the first opening K1.

When the aperture of the second opening K2 is 1 μm to 5 μm, the etching conditions can be improved by appropriately enlarging the aperture, thereby reducing the angle θ2 between the sidewall of the second opening K2 and the second mesa M2.

In this embodiment, the micro-LED is rectangular, with a length of its shorter side not exceeding 15 μm, and each side length of the first mesa M1 not exceeding 15 μm. Micro-scale LEDs are constrained by application-specific size requirements and cannot provide the same area for a first mesa M1 of a conventional LED. An area of the first mesa M1 is smaller than that of the second mesa M2, specifically ½ to ⅘ of the area of the second mesa M2. The second mesa M2 is the main light-emitting region. This embodiment further reduces the first mesa M1 to increase the area of the light-emitting region.

Since the first opening K1 is disposed on the first mesa M1, the smaller the area of the first mesa M1, the larger the light-emitting area of the micro-LED, and the higher the device efficiency. Therefore, the area of the first opening K1 is smaller than that of the second opening K2. An aperture of the first opening K1 ranges from 1 μm to 3 μm, and an aperture of the second opening K2 ranges from 1 μm to 5 μm (here, “aperture” refers to a maximum length of the corresponding opening when viewed from above). The second opening K2 is disposed on the second mesa M2, and an aperture of the second opening K2 is greater than or equal to that of the first opening K1, further reducing the process difficulty of the second opening K2. The angle between the first opening K1 and the first mesa M1 is θ1, and the angle between the second opening K2 and the second mesa M2 is 02, where θ1≤02. The angle θ1 ranges from 20° to 45°, and the angle θ2 ranges from 20° to 60°. By controlling the material types and thicknesses of the insulating layers, this embodiment reduces the angle θ1 during dry etching, particularly lowering the difficulty of angle control. At the same time, the present disclosure reduces the area of the first electrode hole K11, increases an effective bonding area of the first metal electrode 210, and thus improves a bonding yield.

In some implementations of this embodiment, the first insulating layer 310 consists of one dielectric material, while the second insulating layer 320 consists of two or more dielectric materials. The dielectric material of the first insulating layer 310 differs from that of the second insulating layer 320.

In this embodiment, the second insulating layer 320 is disposed on the second mesa M2 and includes an insulating reflective layer 321. A material of the insulating reflective layer 321 is a distributed Bragg reflector (DBR), such as a periodic dielectric stack composed of silicon dioxide and titanium dioxide with more than three periods. The first insulating layer 310 extends from the groove sidewall S1 onto the second mesa M2 and covers the insulating reflective layer 321, forming a portion of the second insulating layer 320. By reducing the thickness and/or material types of the dielectric layer beneath the first metal electrode 210, this embodiment expands the process window for removal (e.g., wet etching or dry etching). To further reduce the process difficulty of the first opening K1 and improve the controllability of its angle, this embodiment employs dry etching to form the first opening K1 as an example.

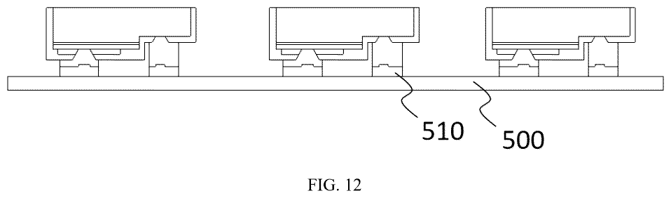

Referring to FIG. 12, in an embodiment 5 of the present disclosure, a display apparatus is provided, includes a circuit board 500 and any one of the aforementioned micro-LEDs. The micro-LED is electrically connected to the circuit board 500 via a bonding layer 510. Through the matching design of the metal electrodes, electrode holes, and grooves of the micro-LED, product yield is improved, particularly in high-pressure, low-temperature bonding processes. For example, the bonding layer 510 may be anisotropic conductive adhesive.

The above descriptions are merely preferred embodiments of the present disclosure and are not intended to limit the disclosure. Any modifications, equivalent substitutions, or improvements made within the spirit and principles of the disclosure shall fall within the scope of protection of the present disclosure.

What is claimed is:

1. A micro light-emitting diode (micro-LED), comprising a semiconductor layer sequence, wherein the semiconductor layer sequence has a back side and a front side opposite to the back side; in a direction from the front side to the back side, the semiconductor layer sequence sequentially comprises: a first-type semiconductor layer, a second-type semiconductor layer, and an active layer between the first-type semiconductor layer and the second-type semiconductor layer; the back side of the semiconductor layer sequence is provided with a groove, the groove penetrates through the second-type semiconductor layer and the active layer, and the first-type semiconductor layer is exposed through the groove; the back side of the semiconductor layer sequence comprises: a first mesa within the groove, a second mesa on the second-type semiconductor layer, and a groove sidewall located between the first mesa and the second mesa; a first metal electrode and a second metal electrode are disposed on the back side of the semiconductor layer sequence, the first metal electrode is electrically connected to the first-type semiconductor layer, and the second metal electrode is electrically connected to the second-type semiconductor layer; the first metal electrode and the second metal electrode are configured for bonding with an external power supply; and the first metal electrode is entirely disposed within the groove.

2. The micro-LED as claimed in claim 1, wherein the micro-LED is rectangular, a length of a shorter side of the micro-LED is not more than 20 μm, a length of a longer side of the micro-LED is not more than 30 μm, a length of each side of the first mesa is not more than 20 μm, and a length of each side of the second mesa is in a range from 5 μm to 20 μm.

3. The micro-LED as claimed in claim 1, wherein the groove is an unenclosed step, three side surfaces of four side surfaces of the groove are exposed, and the remaining side surface of the four side surfaces of the groove is the groove sidewall.

4. The micro-LED as claimed in claim 1, further comprising: a first insulating layer and a second insulating layer;
wherein the first insulating layer defines a first opening disposed on the first mesa; the first metal electrode is partially disposed on the first mesa, the first metal electrode extends from the first mesa within the first opening onto the first insulating layer; the second insulating layer is disposed on the second mesa and defines a second opening disposed on the second mesa; and the second metal electrode is partially disposed on the second mesa, the second metal electrode extends from the second mesa within the second opening onto the second insulating layer.

5. The micro-LED as claimed in claim 4, wherein a material of the first insulating layer is not entirely the same as a material of the second insulating layer, the first insulating layer comprises silicon dioxide, and the second insulating layer comprises titanium dioxide.

6. The micro-LED as claimed in claim 4, wherein a backside surface of the first metal electrode facing away from the first-type semiconductor layer is provided with a first electrode hole corresponding in position to the first opening, and a backside surface of the second metal electrode facing away from the second-type semiconductor layer is provided with a second electrode hole corresponding in position to the second opening; and
wherein an opening area of the first electrode hole is smaller than an opening area of the second electrode hole.

7. The micro-LED as claimed in claim 5, wherein an opening area of the first electrode hole accounts for 10% to 90% of an area of the backside surface of the first metal electrode, and an opening area of the second electrode hole accounts for 10% to 90% of an area of the backside surface of the second metal electrode.

8. The micro-LED as claimed in claim 5, wherein an opening area of the first electrode hole accounts for 10% to 40% of an area of the backside surface of the first metal electrode, and an opening area of the second electrode hole accounts for 10% to 40% of an area of the backside surface of the second metal electrode.

9. The micro-LED as claimed in claim 5, wherein a projected area of the backside surface of the first metal electrode and a projected area of the backside surface of the second metal electrode are each no greater than 100 μm².

10. The micro-LED as claimed in claim 1, wherein a spacing between the first metal electrode and the second metal electrode is in a range from 4 μm to 10 μm.

11. The micro-LED as claimed in claim 1, wherein at least part of the first-type semiconductor layer of the micro-LED is removed in a direction of the front side.

12. The micro-LED as claimed in claim 2, wherein from a projection view of the back side, the second metal electrode is rectangular, the second metal electrode comprises a first side (L21), a second side (L22), a third side (L23), and a fourth side (L24) sequentially connected in that order, the first side (L21) is close to and parallel to the shorter side of the micro-LED, and the second side (L22) and the fourth side (L24) are parallel to the longer side of the micro-LED.

13. The micro-LED as claimed in claim 12, wherein a spacing from the second electrode hole to the third side (L23) is within ½ of a spacing from the second electrode hole to the first side (L21).

14. The micro-LED as claimed in claim 4, wherein from a projection view of the back side, the first metal electrode is rectangular, the first metal electrode comprises a first side (L11), a second side (L12), a third side (L13), and a fourth side (L14) sequentially connected in that order, the first side (L11) is close to and parallel to a shorter side of the micro-LED, the second side (L12) and the fourth side (L14) are parallel to a longer side of the micro-LED, and a spacing from the first electrode hole to the third side (L13) is within ½ of a spacing from the first electrode hole to the first side (L11).

15. The micro-LED as claimed in claim 14, wherein the first electrode hole and the second electrode hole are diagonally arranged relative to a center of the micro-LED.

16. The micro-LED as claimed in claim 6, wherein except for positions corresponding to the first electrode hole and the second electrode hole on the backside surface of the first metal electrode facing away from the first-type semiconductor layer and on the backside surface of the second metal electrode facing away from the second-type semiconductor layer, other positions on the backside surface of the first metal electrode facing away from the first-type semiconductor layer and other positions on the backside surface of the second metal electrode facing away from the second-type semiconductor layer are at a same height.

17. A display apparatus, comprising a circuit board, and the micro-LED as claimed in claim 1, wherein the micro-LED is electrically connected to the circuit board via a bonding layer.

18. A micro-LED, comprising:
a semiconductor layer sequence, having a first side and a second side opposite to the first side, wherein in a direction from the first side to the second side, the semiconductor layer sequence comprises a first-type semiconductor layer, an active layer, and a second-type semiconductor layer sequentially stacked in that order; the second side of the semiconductor layer sequence is provided with a groove, the groove penetrates through the second-type semiconductor layer and the active layer, and the first-type semiconductor layer is partially exposed through the groove; the second side of the semiconductor layer sequence comprises: a first mesa within the groove, a second mesa on the second-type semiconductor layer, and a groove sidewall connecting the first mesa and the second mesa;
a first insulating layer, disposed on the first mesa and having a first opening, wherein a part of the first-type semiconductor layer is exposed from the first opening;
a second insulating layer, disposed on the second mesa and having a second opening, wherein a part of the second-type semiconductor layer is exposed from the second opening;
a first metal electrode, disposed on the first insulating layer and covering the first opening, wherein the first metal electrode is electrically connected to the first-type semiconductor layer, a surface of the first metal electrode facing away from the first-type semiconductor layer is provided with a first electrode hole corresponding in position to the first opening; and
a second metal electrode, disposed on the second insulating layer and covering the second opening, wherein the second metal electrode is electrically connected to the second-type semiconductor layer, a surface of the second metal electrode facing away from the second-type semiconductor layer is provided with a second electrode hole corresponding in position to the second opening;
wherein the first metal electrode is entirely disposed within the groove, the first electrode hole is disposed at a non-central position on the surface of the first metal electrode facing away from the first-type semiconductor layer, and the second electrode hole is disposed at a non-central position on the surface of the second metal electrode facing away from the second-type semiconductor layer; and except for positions corresponding to the first electrode hole and the second electrode hole on the surface of the first metal electrode facing away from the first-type semiconductor layer and on the surface of the second metal electrode facing away from the second-type semiconductor layer, other positions on the surface of the first metal electrode facing away from the first-type semiconductor layer and other positions on the surface of the second metal electrode facing away from the second-type semiconductor layer are at a same height.

19. The micro-LED as claimed in claim 18, wherein a side length of the first mesa is not greater than 20 μm, a side length of the second mesa is in a range from 5 μm to 20 μm, an opening area of the first electrode hole accounts for 10% to 90% of an area of the surface of the first metal electrode facing away from the first-type semiconductor layer, and an opening area of the second electrode hole accounts for 10% to 90% of an area of the surface of the second metal electrode facing away from the second-type semiconductor layer.

20. A micro-LED, comprising:
a semiconductor layer sequence, having a first side and a second side opposite to the first side, wherein in a direction from the first side to the second side, the semiconductor layer sequence comprises a first-type semiconductor layer, an active layer, and a second-type semiconductor layer sequentially stacked in that order; the second side of the semiconductor layer sequence is provided with a groove, the groove penetrates through the second-type semiconductor layer and the active layer, and the first-type semiconductor layer is partially exposed through the groove; the second side of the semiconductor layer sequence comprises: a first mesa within the groove, a second mesa on the second-type semiconductor layer, and a groove sidewall connecting the first mesa and the second mesa;
a first insulating layer, disposed on the first mesa and having a first opening, wherein a part of the first-type semiconductor layer is exposed from the first opening;
a second insulating layer, disposed on the second mesa and having a second opening, wherein a part of the second-type semiconductor layer is exposed from the second opening;
a first metal electrode, disposed on the first insulating layer and covering the first opening, wherein the first metal electrode is electrically connected to the first-type semiconductor layer, a surface of the first metal electrode facing away from the first-type semiconductor layer is provided with a first electrode hole corresponding in position to the first opening; and
a second metal electrode, disposed on the second insulating layer and covering the second opening, wherein the second metal electrode is electrically connected to the second-type semiconductor layer, a surface of the second metal electrode facing away from the second-type semiconductor layer is provided with a second electrode hole corresponding in position to the second opening;
wherein the first metal electrode is entirely disposed within the groove, a thickness of the first insulating layer is ¼ to ⅔ of a thickness of the second insulating layer, an area of the first mesa is ½ to ⅘ of an area of the second mesa, an aperture of the second opening is greater than or equal to an aperture of the first opening, an angle between a sidewall of the first opening and the first mesa is a first angle, an angle between a sidewall of the second opening and the second mesa is a second angle, the first angle is less than or equal to the second angle, the first angle is in a range from 20° to 45°, and the second angle is in a range from 20° to 60°.
